(19) United States
(12) Patent Application Publication
(10) Pub. No.: US 2010/0321094 A1
(43) Pub. Date: Dec. 23, 2010

(54) METHOD AND CIRCUIT IMPLEMENTATION FOR REDUCING THE PARAMETER FLUCTUATIONS IN INTEGRATED CIRCUITS

(76) Inventors: HAO LUO, (US); Yan Han, (US); Xiaoxia Han, (US); Xiaopeng Liu, (US)

Correspondence Address: Yan Han;Dept of Infor. Science & Electronic Engineering, Yuquan Campus, Zhejiang University, No. 38, Zheda Road, Hangzhou, 310027, omitted

(21) Appl. No.: 12/870,833

(22) Filed: Aug. 29, 2010

(51) Int. Cl. H01L 37/00; G05F 1/10

(52) U.S. Cl. 327/513; 327/538

(57) ABSTRACT

This invention provides a method for reducing the effects of process, supply voltage and temperature variations in integrated circuits and its circuit implementation. The disclosed method builds up a detecting-feedback loop with a plurality of target MOS transistors in main circuits, an induction MOS transistor and a current-to-voltage conversion circuit, and performs a body modulation to effectively reduce the parameter fluctuations of the target MOS transistors in a sub-threshold region or a saturated region due to process, supply voltage and temperature variations. A body-modulated circuit achieves the disclosed method with only a few circuit elements, which effectively improves the stability, reliability and product yield of integrated circuits, especially sub-threshold integrated circuits, without significantly increasing the circuit complexity and power consumption.

### BACKGROUND OF THE INVENTION

1. Field of the Invention

The present invention relates to a method for reducing the effects of process, supply voltage and temperature variations in integrated circuits and its circuit implementation, and in particular, to a method building up a detecting-feedback loop (with a plurality of target MOS (Metal-Oxide-Semiconductor) transistors, an induction MOS transistor and a current-to-voltage conversion circuit) for performing body modulation to reduce the parameter fluctuations of the target MOS transistors in a sub-threshold region or a saturated region due to process, supply voltage and temperature variations, and a body-modulated circuit for realizing the aforementioned method and its application in integrated circuits, especially in sub-threshold integrated circuits (class-C inverter, inverter-based integrator, inverter-based ΣΔ (Sigma-Delta) modulator, etc.).

2. Description of the Related Art

The rapid development of portable electronic device market is forcing an explosive growth in the demand for low-voltage micro-power integrated circuits (ICs). However, to avoid leakage current in transistors, the threshold voltage is not scaled as aggressively as the supply voltage with continuing scaling of CMOS technology, which poses significant challenges in low-voltage analog circuit design. Sub-threshold circuit technique is an effective way to solve the above problem because of its ability to operate with very low supply voltage, which is widely applied for low-voltage micro-power IC design environment.

A class-C inverter circuit is reported recently to replace operational transconductance amplifier (OTA) in low-voltage micro-power analog circuits. The input transistors in the class-C circuit behave as class-C amplifiers and operate in a sub-threshold region most of the time, thereby minimizing system power dissipation (refer to Chae et al., “Low Voltage, Low Power, Inverter-Based Switched-Capacitor Delta-Sigma Modulator”, IEEE Journal of Solid-State Circuit, 2009, 44(2):p. 458-472, as cited in references).

However, for a MOS transistor in a sub-threshold region, its parameters, such as transconductance and drain-source current, significantly fluctuate depending upon process, supply voltage and temperature variations, resulting in performance degradation or even malfunction of its application circuits, which disadvantageously affects the stability, reliability and product yield of sub-threshold ICs.

The (Marr et al., U.S. patent application Ser. No. 10/368,068, U.S. Pat. No. 6,809,968) provides systems and methods for solving the stability problems associated with temperature variation for LL4TCMOS SRAM cells by providing a temperature-based body bias. One embodiment provides a bias generator, including a charge pump coupled to a body terminal of the MOS transistor(s), and a comparator coupled to the charge pump. The comparator includes a first input that receives a reference voltage, a second input that receives a threshold-voltage-dependent voltage, and an output that presents a control signal to the charge pump and causes the charge pump to selectively charge the body terminal of the transistor to compensate for temperature changes.

The (Mori et al., U.S. patent application Ser. Nos. 11/169,800 and 11/826,636, U.S. Pat. Nos. 7,245,521 and 7,486,544) adopts the concept of body bias to an SRAM for reducing the gate leak current. The body bias circuit switches different predetermined voltages to a body terminal of a (P-channel or N-channel) MOSFET in the operation state and standby state, thereby reducing the gate leak current in the standby state. Similarly, the (Itoh et al., U.S. patent application Ser. No. 09/027,212, U.S. Pat. No. 6,046,627) realizes a controllable body bias through the turn-on and cut-off of a provided power supply for decreasing the subthreshold current of low-threshold-voltage MOSFETs.

In addition, bidirectional adaptive body bias is reported to compensate for die-to-die parameter variations in microprocessors by applying an optimum PMOS (p-type metal-oxide-semiconductor) and NMOS (n-type metal-oxide-semiconductor) body bias voltage to each die which maximizes the die frequency subject to a power constraint. In this method, one critical path is replicated from microprocessors, and the output of the replica critical path is sampled by a phase detector which compares the critical path delay with a target clock period, and then the output from this phase detector is used to clock a 5-b digital counter whose value represents the desired body bias to apply. Finally, a digital-to-analog converter, consisting of an R-2R resistor network and an OTA, convert this 5-b digital code to an analog body voltage which is applied to the MOS transistors in microprocessors (refer to Tschanz et al., “Adaptive Body Bias for Reducing Impacts of Die-to-Die and Within-Die Parameter Variations on Microprocessor Frequency and Leakage”, IEEE JOURNAL OF SOLID-STATE CIRCUITS, VOL. 37, NO. 11, pp. 1396-1402, November 2002).

However, the body bias voltages of the methods provided by Mori et al. and Itoh et al. are predetermined, which is not suitable for reducing the parameter fluctuations in ICs due to unpredictable process, supply voltage and temperature variations. The methods provided by Marr et al. and Tschanz et al. are only applied to digital ICs for mitigating the effects of temperature dependence and process variation, respectively, which is difficult to simultaneously reduce all disadvantageous effects of process, supply voltage and temperature variations, and which is difficult to directly solve relevant instability problems in analog ICs, especially in sub-threshold ICs. Moreover, in order to provide appropriate body bias, the method described by Marr et al. requires a charge pump, a comparator and a reference voltage generator, while the method proposed by Tschanz et al. adds another power grid section, along with a replica critical path, phase detector, counter, and R-2R ladder digital-to-analog converter. These prove to be enormously expensive in both die area overhead and power consumption.

Therefore, there is a need in the art to provide a method and circuit implementation that reduces the effects of process, supply voltage and temperature variations in analog ICs, especially in sub-threshold ICs, without significantly increasing the circuit complexity and power consumption.

Because of the technical difficulties between the present invention and the cited references, it is absolutely not obvious for a person with ordinary skills in the art to utilize the prior arts to come out the solutions disclosed in the present invention.

### SUMMARY OF THE INVENTION

The object of the invention is to overcome at least some of the drawbacks relating to the compromise designs of prior art systems and methods as discussed above.

An object of the present invention is to provide a method for reducing the effects of process, supply voltage and temperature variations in ICs to solve the above-described problem. Another object of the present invention is to provide a body-modulated circuit for realizing the method above. A third object of the present invention is to provide an application of the body-modulated circuit to ICs, especially sub-threshold ICs, realizing a body-modulated class-C inverter circuit, an inverter-based integrator circuit and an inverter-based ΣΔ (Sigma-Delta) modulator circuit with low process-related, supply-voltage-related and temperature-related sensitivity, high stability and strong practicability as compared with the related prior arts.

According to the first aspect of the present invention, there is provided a method for reducing the effects of process, supply voltage and temperature variations in ICs including the following steps: an induction MOS transistor firstly detects the parameter fluctuation characteristics of target MOS transistors in main circuits under different process corners, supply voltages and temperatures, and outputs a drain-source induction current signal; secondly, a current-to-voltage conversion circuit converses the drain-source induction current signal to an induction voltage signal, and reflects the fluctuation characteristics of the drain-source induction current to the induction voltage in real time; lastly, the induction voltage is fed back to the body of the target MOS transistors, thus a detecting-feedback loop is built up with the target MOS transistors in main circuits, the induction MOS transistor and the current-to-voltage conversion circuit, and performs body modulation for reducing the parameter fluctuations of the target MOS transistors due to process, supply voltage and temperature variations.

According to the second aspect of the present invention, there is provided a body-modulated circuit for realizing the aforementioned method including a plurality of target MOS transistors, an induction MOS transistor, and a current-to-voltage conversion circuit. The target MOS transistors operates in a sub-threshold region or a saturated region in main circuits, and the induction MOS transistor detects the parameter fluctuation characteristics of the target MOS transistors under different process corners, supply voltages and temperatures. The current-to-voltage conversion circuit converses a drain-source induction current signal outputted by the induction MOS transistor to an induction voltage signal, and feeds back the induction voltage signal to the body of the target MOS transistors for body modulation.

The body-modulated circuit is classified as PMOS body-modulated circuit and NMOS body-modulated circuit.

The PMOS body-modulated circuit is used to reduce the parameter fluctuations of PMOS transistors in a sub-threshold region or a saturated region due to process, supply voltage and temperature variations, which includes a plurality of target PMOS transistors, an induction PMOS transistor and a first load circuit. The induction PMOS transistor shares similar operation area with the target PMOS transistors to detect the parameter fluctuation characteristics of the target PMOS transistors under different process corners, supply voltages and temperatures, and the first load circuit functions as the current-to-voltage conversion circuit in the PMOS body-modulated circuit. The target PMOS transistors have their bodies separated from the chip substrate, the induction PMOS transistor has the source connected to the body itself, and has the drain connected to both a first terminal of the first load circuit and the bodies of the target PMOS transistors, and a second terminal of the first load circuit is biased by a common-mode voltage signal.

The NMOS body-modulated circuit is used to reduce the parameter fluctuations of NMOS transistors in a sub-threshold region or a saturated region due to process, supply voltage and temperature variations, which includes a plurality of target NMOS transistors, an induction NMOS transistor and a second load circuit. The induction NMOS transistor shares similar operation area with the target NMOS transistors to detect the parameter fluctuation characteristics of the target NMOS transistors under different process corners, supply voltages and temperatures, and the second load circuit functions as the current-to-voltage conversion circuit in the NMOS body-modulated circuit. The target NMOS transistors have their bodies separated from the chip substrate, the induction NMOS transistor has the source connected to the body itself, and has the drain connected to both a first terminal of the second load circuit and the bodies of the target NMOS transistors, and a second terminal of the second load circuit is biased by the common-mode voltage signal.

Different from the cited art technologies as disclosed in Marr et al. and Tschanz et al., the proposed PMOS and NMOS body-modulated circuits, as set forth above, require only one MOS transistor and a load circuit respectively to provide appropriate body bias (the target MOS transistors belong to the main circuit), which significantly reduces the die area overhead and power consumption.

According to the third aspect of the present invention, there is provided a body-modulated class-C inverter circuit by applying the body-modulated circuit to a traditional class-C inverter. The body-modulated class-C inverter circuit includes a PMOS body-modulated circuit, a NMOS body-modulated circuit and a traditional class-C inverter. The PMOS body-modulated circuit and the NMOS body-modulated circuit are introduced to reduce the parameter fluctuations of said body-modulated class-C inverter due to process, supply voltage and temperature variations, and the traditional class-C inverter performs an operational amplification function.

In the aforementioned body-modulated class-C inverter circuit, the PMOS body-modulated circuit includes a target PMOS transistor, an induction PMOS transistor and a first load circuit. And the NMOS body-modulated circuit includes a target NMOS transistor, an induction NMOS transistor and a second load circuit. In addition, the traditional class-C inverter includes a PMOS input transistor and a NMOS input transistor operating in a sub-threshold region most of the time.

Further, in the aforementioned body-modulated class-C inverter circuit, the PMOS input transistor included in the traditional class-C inverter is treated as the target PMOS transistor in the PMOS body-modulated circuit. And the NMOS input transistor included in the traditional class-C inverter is treated as the target NMOS transistor in the NMOS body-modulated circuit.

According to the third aspect of the present invention, there is provided an inverter-based integrator by applying the body-modulated class-C inverter circuit to an analog integrator. According to circuit architecture, the inverter-based integrator can be classified as a single-ended inverter-based integrator and a pseudo-differential inverter-based integrator.

A single-ended inverter-based integrator circuit includes a body-modulated class-C inverter circuit, a sampling capacitor, an integrating capacitor, a compensating capacitor, an input, an output and switches. The body-modulated class-C inverter circuit performs an operational amplification instead of a traditional OTA. The sampling capacitor samples input signal during a sampling clock phase, the integrating capacitor integrates the signal in the sampling capacitor during an integrating clock phase, and the compensating capacitor samples the offset of the body-modulated class-C inverter during the sampling phase and compensates the effect of the offset during the integrating phase. An input is used to receive an input signal, and an output provides an integrated signal. Switches included in the inverter-based integrator circuit controls signal transmission during both clock phases.

A pseudo-differential inverter-based integrator circuit includes a pair of single-ended inverter-based integrator circuits. The pair of single-ended inverter-based integrator circuits is placed symmetrically in differential branches to build a pseudo-differential configuration. The pseudo-differential inverter-based integrator circuit further includes a pair of body-modulated class-C inverter circuits for performing a pseudo-differential operational amplification instead of a traditional differential OTA.

According to the third aspect of the present invention, there is provided an inverter-based ΣΔ modulator circuit by applying the body-modulated class-C inverter circuit to a ΣΔ modulator. The inverter-based ΣΔ modulator circuit includes several single-ended or pseudo-differential inverter-based integrator circuits, and performs a ΣΔ analog-to-digital conversion on an input signal. The inverter-based ΣΔ modulator circuit further includes several (pairs of) body-modulated class-C inverter circuits for performing an operational amplification instead of traditional (differential) OTAs.

Therefore, the method for reducing the effects of process, supply voltage and temperature variations in ICs according to the present invention can modulate the electrical parameters of the target MOS transistors in real time through body modulation performed by the detecting-feedback loop, and effectively reduce parameter fluctuations of the target MOS transistors in a sub-threshold region or a saturated region due to process, supply voltage and temperature variations as compared with the prior art. The body-modulated circuit according to the present invention can achieve the entire detecting-feedback loop with only a few circuit elements, and effectively improve the stability, reliability and product yield of ICs, especially sub-threshold ICs, without significantly increasing the circuit complexity and power consumption, which is particularly suitable in ultra-low-power design environment.

The details of the present invention are disclosed in the following drawings, descriptions as well as the claims based on the abovementioned elements.

The various aspects, features and advantages of the disclosure will become more fully apparent to those having ordinary skill in the art upon careful consideration of the following detailed description thereof with the accompanying drawings described below.

### BRIEF DESCRIPTION OF THE DRAWINGS

These and other objects and features of the present invention will become clear from the following description taken in conjunction with the preferred embodiments thereof with reference to the accompanying drawings throughout which similar constituent elements are denoted by the same reference symbols, and in which:

FIG. 1 is a flowchart describing a method for reducing the effects of process, supply voltage and temperature variations according to a preferred embodiment of the present invention;

FIG. 2 is a circuit diagram showing a PMOS body-modulated circuit according to a preferred embodiment of the present invention;

FIG. 3 is a circuit diagram showing a NMOS body-modulated circuit according to a preferred embodiment of the present invention;

FIG. 4 is a circuit diagram showing a class-C inverter according to the prior art;

FIG. 5 is a circuit diagram showing a body-modulated class-C inverter according to a preferred embodiment of the present invention;

FIG. 6 is a circuit diagram showing a single-ended inverter-based integrator according to a preferred embodiment of the present invention;

FIG. 7 is a circuit diagram showing a pseudo-differential inverter-based integrator according to a preferred embodiment of the present invention;

FIG. 8 is a circuit diagram showing an inverter-based ΣΔ modulator according to a preferred embodiment of the present invention.

Like reference numerals refer to like parts throughout the several views of the drawings.

### DETAILED DESCRIPTION OF THE PREFERRED EMBODIMENTS

The present inventions now will be described more fully hereinafter with reference to the accompanying drawings, in which some examples of the embodiments of the inventions are shown. Indeed, these inventions may be embodied in many different forms and should not be construed as limited to the embodiments set forth herein; rather, these embodiments are provided by way of example so that this disclosure will satisfy applicable legal requirements. Like numbers refer to like elements throughout.

The key element of the method for reducing the effects of process, supply voltage and temperature variations according to the present invention lies in body modulation. As we known, the threshold voltage (V_{T}) of a MOS transistor satisfies the following relationship:

V_{T}=V_{T0}+γ(\sqrt{2|φ_{F}|+v_{SB}}−\sqrt{2|φ_{F}|})

where v_{SB} is the source-body voltage of the MOS transistor, V_{T0} is the threshold voltage when v_{SB}=0, γ is body threshold parameter, and φ_{F} is referred to as Fermi potential. Therefore, referring to the formula above, the threshold voltage of a MOS transistor, as well as the parameters of transconductance and output current, can be modulated through adjusting the body potential (changing the source-body voltage v_{SB}).

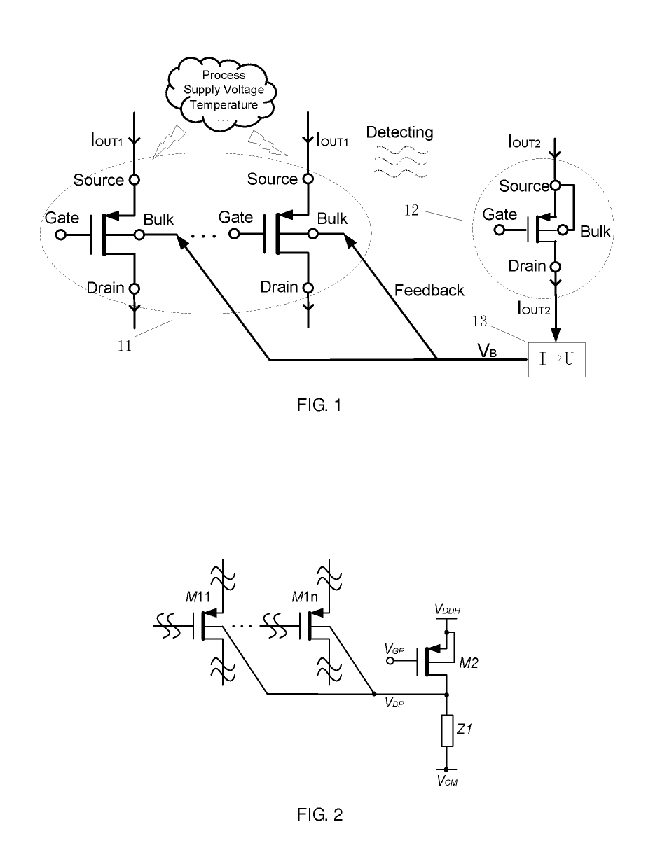

FIG. 1 is a flowchart describing a method for reducing the effects of process, supply voltage and temperature variations according to one preferred embodiment of the present invention. As shown in FIG. 1, the method employs a plurality of target PMOS transistors 11 in main circuits, an induction PMOS transistor 12 and a current-to-voltage conversion circuit 13 in the implementation process.

The target PMOS transistors 11, operating in a sub-threshold region or a saturated region, separate their bodies from the chip substrate for achieving adjustable body potential. In the triple-well process, MOS transistors are capable of controlling their body potential separated from the substrate potential.

The induction PMOS transistor 12 detects the parameter fluctuation characteristics of the target PMOS transistors 11 under different process corners, supply voltages and temperatures. The induction PMOS transistor 12 is designed to share the similar operation area and well-matched layout with the target PMOS transistors 11. Therefore, the two share nearly the same situation of process variation at any time points, that is, share the same fluctuation characteristics of electrical parameters. In other words, the induction PMOS transistor 12 behaves as a sensor to detect the parameter fluctuation characteristics of the target PMOS transistors 11 under different process corners, supply voltages and temperatures.

The current-to-voltage conversion circuit 13 converses the induction current signal outputted by the induction PMOS transistor 12 to an induction voltage signal, and feeds back the induction voltage signal to the bodies of the target PMOS transistors 11. Thus a detecting-feedback loop is built up with the target PMOS transistors 11, the induction PMOS transistor 12 and the current-to-voltage conversion circuit 13.

The principle that how the detecting-feedback loop operates to compensate the effect of process variation is explained in detail as follows:

Suppose that process variation initially leads to a decrease in the output current I_{OUT1} of target PMOS transistors 11, the induction current I_{OUT2} of an induction PMOS transistor 12 decreases correspondingly because the induction PMOS transistor 12 is capable of detecting the parameter fluctuation characteristics of the target PMOS transistors 11 under different process corners. A current-to-voltage conversion circuit 13 is designed to converse the induction current I_{OUT2} to an induction voltage V_{B} and reflect the fluctuation characteristics of I_{OUT2} to the induction voltage V_{B} in real time, thus the induction voltage V_{B} decreases as the induction current I_{OUT2} decreases. The decreased induction voltage V_{B} arrives at the bodies of the target PMOS transistors 11 for performing the body modulation, which leads to a decrease in the absolute value of the threshold voltage of the target PMOS transistors 11, as well as an increase in parameters of transconductance and output current. Therefore, a negative feedback is developed by the entire detecting-feedback loop to achieve an efficient compensation for the parameter fluctuation of the target PMOS transistor 11 ultimately.

It is easy to deduce that the effects of supply voltage and temperature variations on PMOS transistors can be effectively reduced through the same detecting-feedback loop. For the NMOS transistors, the establishment of a detecting-feedback loop is in a similar way.

About the method for reducing the effects of process, supply voltage and temperature variations according to the present invention, it is to be noted that:

(a) The body connection mode of the target MOS transistors is different from that of the induction MOS transistor. The target MOS transistors separate their bodies from the chip substrate for achieving adjustable body potential, while the body connection mode of the induction MOS transistor follows conventional rule that the bodies of the induction NMOS and PMOS transistor are connected to low and high electrical levels, respectively, since the induction MOS transistor need reflect the impact of process, supply voltage and temperature variations accurately.
(b) For trade-off considerations among factors such as die area overhead, power consumption and matching accuracy, it is suggested that the ratio of the channel width of the induction MOS transistor to that of the target MOS transistors is between ⅛ and 1/20, and the two share the same channel length.
(c) Since MOS transistors in a sub-threshold area are extremely sensitive to the issue of process, supply voltage and temperature variations, the method according to the present invention is often used in sub-threshold IC design.

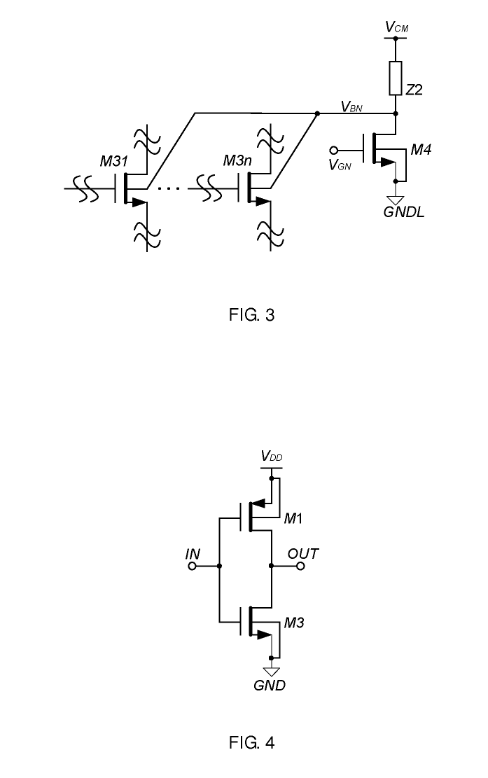

FIGS. 2 and 3 are circuit diagrams showing a PMOS body-modulated circuit and a NMOS body-modulated circuit according to one preferred embodiment of the present invention, respectively.

The PMOS body-modulated circuit includes a plurality of target PMOS transistors M1 (from M11 to M1n), an induction PMOS transistor M2 and a load circuit Z1. The target PMOS transistors M1 operate in a sub-threshold region or a saturated region, and the connections of their gates, drains and sources are provided by the main circuit to which it belongs. Through the setup of the gate-source voltage (V_{GP}-V_{DDH}), the induction PMOS transistor M2 is biased at the same operation area as the target PMOS transistors M1 in order to detect the parameter fluctuation characteristics of the target PMOS transistors M1. The load circuit Z1 (for example, a resistor) converses the induction current outputted by the induction PMOS transistor M2 to an induction voltage V_{BP}, and feeds it back to the bodies of the target PMOS transistors M1. Therefore, a detecting-feedback loop is built up for body modulation. The source potential V_{DDH} of the induction PMOS transistor M2 determines the upper limit of the body-modulated voltage, that is, determines the maximum value of the induction voltage V_{BP}, which can be set according to actual application, while the common-mode voltage V_{CM} determines the lower limit of the body-modulated voltage.

The NMOS body-modulated circuit includes a plurality of target NMOS transistors M3 (from M31 to M3n), an induction NMOS transistor M4 and a load circuit Z2. Similarly, the source potential GNDL of the induction NMOS transistor M4 determines the lower limit of the body-modulated voltage, while the common-mode voltage V_{CM} determines the upper limit of the body-modulated voltage.

Referring to the aforementioned method for reducing the effects of process, supply voltage and temperature variations in integrated circuits, the principle that how the body-modulated circuit operates to compensate the effect of process variation is further explained-taking the PMOS body-modulated circuit for example:

Suppose process corner is tt (typical-typical), and the induction current of the induction PMOS transistor M2 under tt corner is referred to as I_{OUT2}_{_{—}}ₜₜ,

an adjustment of the induction current I_{OUT2}_{_{—}}ₜₜ for a fixed load circuit Z1 is firstly implemented through changing the aspect ratio and the source potential V_{DDH} of the induction PMOS transistor M2 to make the induction voltage V_{BP} signal satisfy the relationship V_{BP}=V_{CM}+I_{OUT2}_{_{—}}ₜₜ·Z1≈V_{DD}, where V_{DD} is power supply voltage.

When process corner is ss (slow-slow), the absolute value of the threshold voltage of the target PMOS transistors M1 increases as compared with the condition under tt corner, leading to a decrease in the transconductance and output current of M1, especially when the target PMOS transistors M1 operates in the sub-threshold region. Due to the sensor role of the induction PMOS transistor M2, the induction current under ss corner I_{OUT2}_{_{—}}ₛₛ also decreases. The induction voltage V_{BP} signal, which satisfies V_{BP}=V_{CM}+I_{OUT2}_{_{—}}ₛₛ·Z1<V_{DD}, arrives at the bodies of the target PMOS transistors M1 for a forward body modulation, leading to a decrease in the absolute value of the threshold voltage, as well as an increase in the transconductance and output current of the target PMOS transistors M1. Therefore, a negative feedback is developed to effectively reduce the process-related sensitivity of the target PMOS transistors M1.

When process corner is ff (fast-fast), the transconductance and output current of the target PMOS transistors M1 increase, along with an increase in the induction current I_{OUT2}_{_{—}}_{ff} of the induction PMOS transistor M2. The relationship V_{BP}=V_{CM}+I_{OUT2}_{_{—}}_{ff}·Z1>V_{DD} is satisfied for a reverse body modulation so that the transconductance and output current of M1 decreases, and power consumption is reduced. It is to be noted that the reverse body modulation under ff corner is only effective when V_{DDH}>V_{DD}, since the source potential V_{DDH} of M2 determines the upper limit of the body-modulated voltage.

Therefore, the PMOS body-modulated circuit is capable of providing corresponding body-modulated voltage signals to compensate the parameter fluctuation of the target PMOS transistors M1 under all process corner conditions.

In a similar way, the parameter fluctuation of the target PMOS transistors M1 due to supply voltage and temperature variations can be also compensated by the PMOS body-modulated circuit. The NMOS body-modulated circuit operates in a way similar to the PMOS body-modulated circuit to compensate the parameter fluctuation of the target NMOS transistors M3.

About the body-modulated circuit according to the present invention, it is to be noted that:

(a) The load circuits Z1 and Z2 should be of low sensitivities to process, supply voltage and temperature variations. For example, off-chip resistors, on-chip poly resistors, MOS transistors in a saturated region, combinations of MOS transistors in a saturated region, etc.
(b) In the PMOS body-modulated circuit, the body-modulated voltage should not be too low, otherwise the source-body junction of the target PMOS transistor M1 will be overly positive-biased to cause excessive leakage current; similarly, the body-modulated voltage in the NMOS body-modulated circuit should not be too high, otherwise the body-source junction of the target NMOS transistor M3 will be overly positive-biased.
(c) In the PMOS body-modulated circuit, the source potential V_{DDH} of the induction PMOS transistor M2 is generally greater than or equal to the power supply voltage V_{DD} of the main circuit to which the target PMOS transistors M1 belongs; similarly, the source potential GNDL of the induction NMOS transistor M4 in the NMOS body-modulated circuit is less than or equal to the ground potential GND of the main circuit to which the target NMOS transistors M3 belongs. When satisfying the relationships V_{DDH}>V_{DD} and/or GNDL<GND, the effect of the body modulation is enhanced with an enlarged body-modulated voltage range, but additional one or two biased electrical levels need be introduced. If no additional level is introduced (V_{DDH}=V_{DD} and/or GNDL=GND), the body-modulated circuit is still effective to compensate the performance degradation of ICs due to relatively slow process corner, low supply voltage and low temperature.
(d) To avoid providing too many biased levels in the PMOS body-modulated circuit, the gate potential V_{GP} of the induction PMOS transistor M2 can share with the power supply voltage V_{DD} (when V_{DDH}>V_{DD}) or the common-mode voltage V_{CM} (when V_{DDH}=V_{DD}); in the NMOS body-modulated circuit, the gate potential V_{GN} of the induction NMOS transistor M4 shares with the ground potential GND (when GNDL<GND) or the common-mode voltage V_{CM} (when GNDL=GND).

FIG. 4 is a circuit diagram showing a class-C inverter according to the prior art. Its supply voltage is slightly lower than the sum of the threshold voltage of PMOS and NMOS input transistors, and both of the input transistors will stay in the sub-threshold region when the common-mode voltage V_{CM}=V_{DD}/2 is inputted, resulting in high DC-gain, ultra low power consumption at cost of high sensitivities to process, supply voltage and temperature variations.

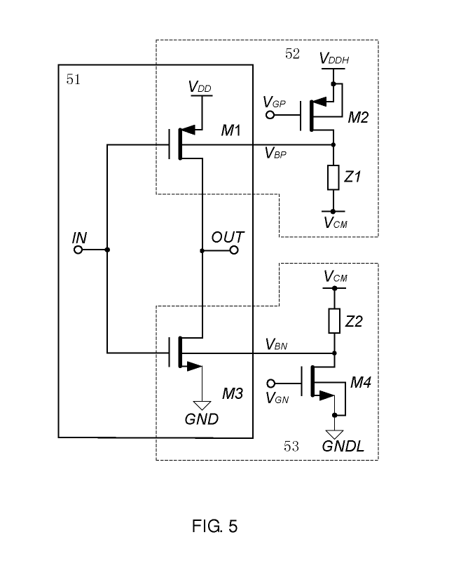

FIG. 5 is a circuit diagram showing a body-modulated class-C inverter according to one preferred embodiment of the present invention. Based on a traditional class-C inverter 51, a PMOS body-modulated circuit 52 and a NMOS body-modulated circuit 53 are introduced to reduce the parameter fluctuations of the PMOS and NMOS input transistors in the body-modulated class-C inverter due to process, supply voltage and temperature variations. In fact, the transconductance and output current of the input transistors are directly related to the parameter characteristics of a class-C inverter, including the specifications of DC-gain, bandwidth and power consumption. Hence, with the introduction of the PMOS and NMOS body-modulated circuits, the sensitivities of the body-modulated class-C inverter to process, supply voltage and temperature variations will be greatly reduced.

The data analysis is based on the body-modulated class-C inverter under different process corners. The steady-state specifications of three types of body-modulated class-C inverters under different process corners as compared with the prior art are listed in TAB. 1. The inverters are all implemented with 1.2-V power supply, 0-V ground potential and 5-pF capacitive load, and inverter sizes are given below: (W/L)₁=180 μm/0.35 μm, (W/L)₃=60 μm/0.35 μm, (W/L)₂=(W/L)₁/12, (W/L)₄=(W/L)₃/12.

According to TAB. 1, when both positive and negative biased electrical levels are introduced (V_{DDH}=1.8 V, GNDL=−0.6 V), the maximum deviations of DC-gain, bandwidth and power consumption in the body-modulated class-C inverter under different process corners are 27.8%, 52.3% and 8%, respectively. Compared to the corresponding 28%, 435.8% and 577.4% in the class-C inverter according the prior art, the body-modulated class-C inverter displays a significant reduction of process-related sensitivity—unexpected power consumption is avoided under ff corner, and sufficient transconductance and bandwidth are guaranteed under ss corner. If only an additional positive level (V_{DDH}=1.8 V, GNDL=0 V) is introduced considering that the on-chip negative level is difficult to produce, the maximum deviations of DC-gain, bandwidth and power consumption in the body-modulated class-C inverter are 29.1%, 169.3% and 81.9%, respectively. If no additional level is introduced (V_{DDH}=1.2V, GNDL=0V), the corresponding maximum deviations are 25.5%, 287.0% and 425.7%, which are still better than those of the class-C inverter according to the prior art. Especially, the unity-gain bandwidth of the class-C inverter according to the prior art is only 5.283 MHz, which possibly leads to malfunction at relatively high frequency circuits, while the bandwidth deterioration problem can be effectively solved in the body-modulated class-C inverter, whether additional biased levels are introduced or not.

TABLE 1
Steady-state specification comparison of class-C inverters: The phase margins of these four class-C inverters
are all over 90°, and the deviation ranges are less than 4% under different process corners.

| | | | | | Unity-gain | | | static power | | |
|---|---|---|---|---|---|---|---|---|---|---|
| | Process | DC-gain | | Deviation | bandwidth | | Deviation | consumption | | Deviation |
| Class-C inverter | corner | (dB) | | range | (MHz) | | range | (μW) | | range |
| Prior art | ff | 29.89 | −2.16% | 28.8% | 169 | 349.83% | 435.8% | 234.3 | 489.58% | 577.4% |
| | snfp | 36.15 | 18.33% | | 37.65 | 0.21% | | 31.75 | −20.1% | |
| | tt | 30.55 | | | 37.57 | | | 39.74 | | |
| | fnsp | 27.34 | −10.5% | | 82.48 | 119.54% | | 49.85 | 25.44% | |
| | ss | 31.57 | 3.34% | | 5.283 | −85.94% | | 4.86 | −87.77% | |
| Present invention | ff | 27.76 | −9.64% | 27.8% | 64.61 | 48.70% | 52.3% | 43.92 | −6.43% | 8% |
| (body-modulated | snfp | 33.79 | 9.99% | | 45.65 | 5.06% | | 45.34 | −3.41% | |
| V_{DDH} = 1.8 V | tt | 30.72 | | | 43.45 | | | 46.94 | | |
| GNDL = −0.6 V) | fnsp | 28.85 | −6.09% | | 49.72 | 14.43% | | 46.6 | −0.72% | |
| | ss | 36.3 | 18.16% | | 41.90 | −3.57% | | 43.2 | −7.97% | |
| Present invention | ff | 27.37 | −10.88% | 29.1% | 110.8 | 153.08% | 169.3% | 54.84 | 20.26% | 81.9% |
| (body-modulated | snfp | 34.03 | 10.81% | | 44.35 | 1.3% | | 48 | 5.26% | |
| V_{DDH} = 1.8 V | tt | 30.71 | | | 43.78 | | | 45.6 | | |
| GNDL = 0 V) | fnsp | 29.46 | −4.07% | | 115.5 | 163.82% | | 78.8 | 72.81% | |
| | ss | 36.31 | 18.24% | | 41.4 | −5.44% | | 41.46 | −9.08% | |
| Present invention | ff | 29.91 | −2.41% | 25.5% | 170.3 | 271.59% | 287.0% | 240.6 | 407.59% | 425.7% |
| (body-modulated | snfp | 34.41 | 12.27% | | 47.19 | 2.97% | | 51.1 | 7.8% | |
| V_{DDH} = 1.2 V | tt | 30.65 | | | 45.83 | | | 47.4 | | |
| GNDL = 0 V) | fnsp | 28.25 | −7.83% | | 96.16 | 109.82% | | 60.42 | 26.84% | |
| | ss | 36.06 | 17.65% | | 38.75 | −15.45% | | 38.84 | −18.06% | |

The maximum deviations of the aforementioned four types of class-C inverters under different process corners are summarized in TAB. 2.

TABLE 2
Maximum deviations of class-C inverters in performance under different process corners

| | static power consumption | | DC-gain | | unity-gain bandwidth | |
|---|---|---|---|---|---|---|
| | Deviation | Optimization | Deviation | Optimization | Deviation | Optimization |
| Class-C inverter | range | rate | range | rate | range | rate |
| Prior art | 577.4% | | 28.8% | | 435.8% | |
| Present invention | 8% | 98.6% | 27.8% | 3.5% | 52.3% | 88.0% |
| (V_{DDH} = 1.8V | | | | | | |
| GNDL = −0.6 V) | | | | | | |
| Present invention | 81.9% | 85.8% | 29.1% | −1.0% | 169.3% | 61.2% |
| (V_{DDH} = 1.8 V | | | | | | |
| GNDL = 0 V) | | | | | | |
| Present invention | 425.7% | 26% | 25.5% | 11.5% | 287.0% | 34% |
| (V_{DDH} = 1.2 V | | | | | | |
| GNDL = 0 V) | | | | | | |

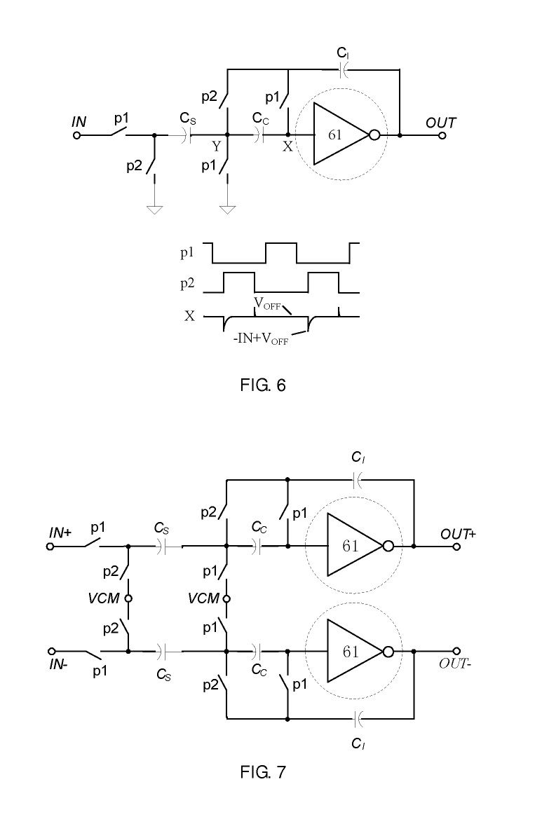

FIG. 6 is a circuit diagram showing a single-ended inverter-based integrator according to one preferred embodiment of the present invention. The single-ended inverter-based integrator includes a body-modulated class-C inverter circuit 61 for performing an operational amplification instead of a traditional OTA, and operates with a two-phase, non-overlapping clocking scheme, including the sampling phase p1 and the integration phase p2, as shown in FIG. 6. During p1, the input signal IN is sampled in the sampling capacitor C_{S}, and the input of the body-modulated class-C inverter 61 (node X) is closely to the signal ground (only offset voltage V_{OFF}). Thus, both input transistors of the body-modulated class-C inverter operate in a sub-threshold region, achieving high DC-gain and micro-power consumption. At the beginning of p2, V_{X} is instantaneously changed to −V_{IN}+V_{OFF} as shown in FIG. 6. Depending on the polarity of the input, one of the input transistors is biased at saturate region while the other is completely off. As a result, a high slew rate is obtained, and the charge in C_{S} is rapidly transferred to the integrating capacitor C_{I}. After settling, V_{X} will gradually return to V_{OFF}, and the body-modulated class-C inverter 61 enters back to the sub-threshold state, thereby removing unnecessary power consumption. Considering that the inverter has only one input terminal and does not provide inherent virtual ground, a compensating capacitor C_{C} is employed to sample the offset voltage V_{OFF} at p1, and holds V_{OFF} to compensate the bottom-plate of C_{C} (node Y) as a virtual ground.

FIG. 7 is a circuit diagram showing a pseudo-differential inverter-based integrator according to one preferred embodiment of the present invention. In the pseudo-differential inverter-based integrator, a pair of single-ended inverter-based integrator circuits is placed symmetrically in differential branches to build a pseudo-differential configuration improving noise immunity, reducing nonlinearities, and increasing the maximum signal swing.

With the introduction of the body-modulated class-C inverters 61, the (single-ended or pseudo-differential) inverter-based integrators exhibit relatively low sensitivities to process, supply voltage and temperature variations on specifications of settling time and power consumption as compared with the related prior arts.

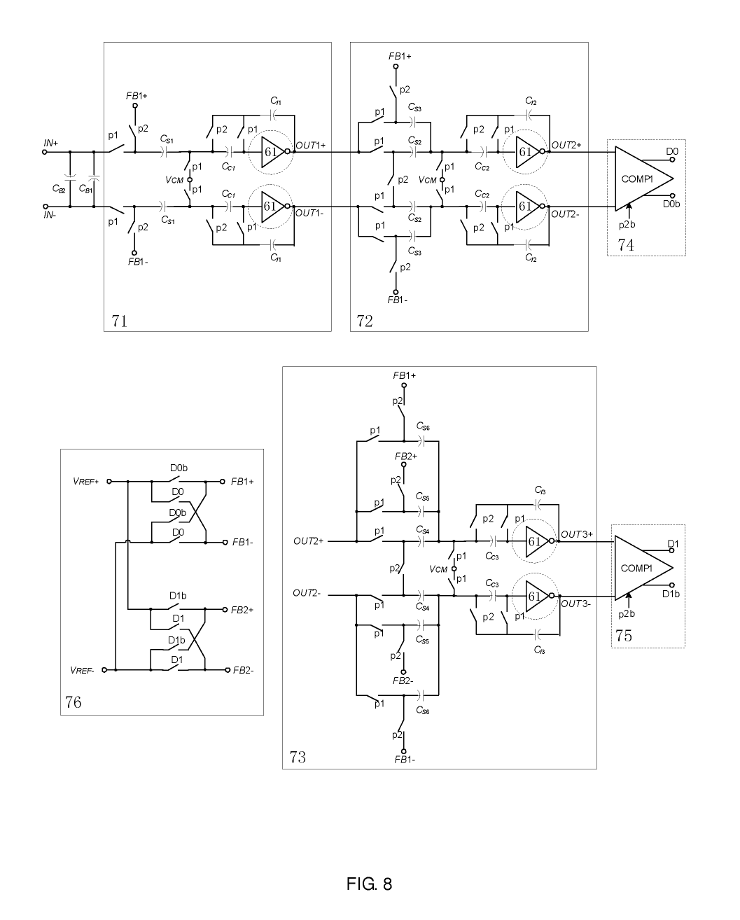

An inverter-based ΣΔ modulator circuit performs a ΣΔ analog-to-digital conversion on an input signal, which includes several (single-ended or pseudo-differential) inverter-based integrator circuits according to the preferred embodiment of the present invention. The inverter-based integrator circuits are placed in series to build a single-loop ΣΔ modulator, or implement a cascaded ΣΔ modulator by using a cascade of single-loop ΣΔ modulators. FIG. 8 is a circuit diagram showing an inverter-based ΣΔ modulator according to one preferred embodiment of the present invention. The inverter-based ΣΔ modulator includes three pseudo-differential inverter-based integrator circuits 71, 72 and 73, two comparators 74 and 75, and a digital-to-analog converter 76, wherein the pseudo-differential inverter-based integrator circuits 71, 72 construct a second-order single-loop ΣΔ modulator and a 2-1 cascaded architecture is built up by cascading the second-order single-loop ΣΔ modulator with the pseudo-differential inverter-based integrator circuit 73. In addition, the two comparators 74 and 75 implement a 1-bit quantization for the outputs (OUT2±, OUT3±) of the pseudo-differential inverter-based integrators 72 and 73, respectively, and the digital-to-analog converter 76 converts the digital signals (D0, D0b, D1, D1b) outputted by the comparators 74 and 75 into analog feedback signals (FB1±, FB2±) for the inputs of the inverter-based integrator circuits 71, 72 and 73.

With the introduction of the body-modulated class-C inverters 61, the inverter-based ΣΔ modulator circuit exhibits relatively low sensitivities to process, supply voltage and temperature variations on specifications of dynamic range and power consumption as compared with the related prior art.

Since many modifications, variations and changes in detail can be made to the described preferred embodiment of the invention, it is intended that all matters in the foregoing description and shown in the accompanying drawings be interpreted as illustrative and not in a limiting sense. Thus, the scope of the invention should be determined by the appended claims and their legal equivalents.

Furthermore, many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific examples of the embodiments disclosed and that modifications and other embodiments are intended to be included within the scope of the appended claims. Although specific terms are employed herein, they are used in a generic and descriptive sense only and not for purposes of limitation.

1. A method for reducing the effects of process, supply voltage and temperature variations in integrated circuits, said method comprising following steps:
a) An induction MOS (Metal-Oxide-Semiconductor) transistor detecting the parameter fluctuation characteristics of target MOS transistors in main circuits under different process corners, supply voltages and temperatures, and outputting a drain-source induction current signal,
b) A current-to-voltage conversion circuit converting said drain-source induction current signal to an induction voltage signal, and reflecting the fluctuation characteristics of said drain-source induction current to said induction voltage in real time, and
c) Said induction voltage fed back to the body of said target MOS transistors, thus a detecting-feedback loop being built up with said target MOS transistors in main circuits, said induction MOS transistor and said current-to-voltage conversion circuit, and performing body modulation for reducing the parameter fluctuations of said target MOS transistors due to process, supply voltage and temperature variations.

2. A method as recited in claim 1, wherein said body modulation circuit comprising:
a) A plurality of said target MOS transistors in a sub-threshold region or a saturated region in main circuits,
b) Said induction MOS transistor for detecting the parameter fluctuation characteristics of said target MOS transistors under different process corners, supply voltages and temperatures, and
c) Said current-to-voltage conversion circuit for converting said drain-source induction current signal outputted by said induction MOS transistor to said induction voltage signal, and feeding back said induction voltage signal to the body of said target MOS transistors for said body modulation.

3. A method as recited in claim 2, wherein said body modulation circuit is classified as PMOS (p-type MOS) body-modulated circuit and NMOS (n-type MOS) body-modulated circuit.

4. A method as recited in claim 3, wherein said PMOS body-modulated circuit is used to reduce the parameter fluctuations of PMOS transistors in a sub-threshold region or a saturated region due to process, supply voltage and temperature variations, and comprises a plurality of target PMOS transistors, an induction PMOS transistor and a first load circuit functioning as said current-to-voltage conversion circuit in said PMOS body-modulated circuit.

5. A method as recited in claim 3, wherein said NMOS body-modulated circuit is used to reduce the parameter fluctuations of NMOS transistors in a sub-threshold region or a saturated region due to process, supply voltage and temperature variations, and comprises a plurality of target NMOS transistors, an induction NMOS transistor and a second load circuit functioning as said current-to-voltage conversion circuit in said NMOS body-modulated circuit.

6. A method as recited in claim 4, wherein said target PMOS transistors have their bodies separated from chip substrate, and said induction PMOS transistor has its source connected to the body itself and has its drain connected to both a first terminal of said first load circuit and the bodies of said target PMOS transistors, and a second terminal of said first load circuit is biased by a common-mode voltage signal.

7. A method as recited in claim 4, wherein said induction PMOS transistor shares similar operation area with said target PMOS transistors to detect the parameter fluctuation characteristics of said target PMOS transistors under different process corners, supply voltages and temperatures.

8. A method as recited in claim 4, wherein said first load circuit has low sensitivities to process, supply voltage and temperature variations which includes for example, off-chip resistor, on-chip poly resistor, MOS transistor in a saturated region or combinations of MOS transistors in a saturated region.

9. A method as recited in claim 5, wherein said target NMOS transistors have their bodies separated from chip substrate, and said induction NMOS transistor has its source connected to the body itself, and has its drain connected to both a first terminal of said second load circuit and the bodies of said target NMOS transistors, and a second terminal of said second load circuit is biased by said common-mode voltage signal.

10. A method as recited in claim 5, wherein said induction NMOS transistor shares similar operation area with said target NMOS transistors to detect the parameter fluctuation characteristics of said target NMOS transistors under different process corners, supply voltages and temperatures.

11. A method as recited in claim 5, wherein said second load circuit has low sensitivities to process, supply voltage and temperature variations which includes for example, off-chip resistor, on-chip poly resistor, MOS transistor in a saturated region or combinations of MOS transistors in a saturated region.

12. A body-modulated class-C inverter circuit, said system comprising:
a) A PMOS (p-type Metal-Oxide-Semiconductor) body-modulated circuit and a NMOS (n-type Metal-Oxide-Semiconductor) body-modulated circuit for reducing the parameter fluctuations of a body-modulated class-C inverter due to process, supply voltage and temperature variations, and
b) A traditional class-C inverter for performing an operational amplification.

13. A system as recited in claim 12, wherein said PMOS body-modulated circuit comprising:
a) A target PMOS transistor,
b) An induction PMOS transistor for detecting the parameter fluctuation characteristics of said target PMOS transistor under different process corners, supply voltages and temperatures, and
c) A first load circuit for converting a drain-source induction current signal outputted by said induction PMOS transistor to an induction voltage signal, and feeding back said induction voltage signal to the body of said target PMOS transistor for body modulation.

14. A system as recited in claim 12, wherein said NMOS body-modulated circuit comprising:
a) A target NMOS transistor,
b) An induction NMOS transistor for detecting the parameter fluctuation characteristics of said target NMOS transistor under different process corners, supply voltages and temperatures, and
c) A second load circuit for converting a drain-source induction current signal outputted by said induction NMOS transistor to an induction voltage signal, and feeding back said induction voltage signal to the body of said target NMOS transistor for body modulation.

15. A system as recited in claim 12, wherein said traditional class-C inverter comprises a PMOS input transistor and a NMOS input transistor operating in a sub-threshold region most of the time.

16. A system as recited in claim 15, wherein said PMOS input transistor is treated as said target PMOS transistor in said PMOS body-modulated circuit, and said NMOS input transistor is treated as said target NMOS transistor in said NMOS body-modulated circuit.

17. A single-ended inverter-based integrator circuit, said system comprising:
a) A body-modulated class-C inverter circuit for performing an operational amplification instead of a traditional OTA (operational transconductance amplifier),
b) A sampling capacitor for sampling input signal during a sampling clock phase,
c) An integrating capacitor for integrating the signal in said sampling capacitor during an integrating clock phase,
d) A compensating capacitor for sampling the offset of said body-modulated class-C inverter during the sampling phase and compensating the effect of the offset during said integrating phase,
e) An input for receiving an input signal,
f) An output for providing an integrated signal, and
g) Switches for controlling signal transmission during both clock phases.

18. A system as recited in claim 17, wherein said pair of single-ended inverter-based integrator circuits is placed symmetrically in differential branches to build a pseudo-differential inverter-based integrator circuit configuration.

19. A system as recited in claim 18, wherein said pseudo-differential inverter-based integrator circuit further comprises a pair of said body-modulated class-C inverter circuits included in said single-ended inverter-based integrator circuits, and said pair of body-modulated class-C inverter circuits performs a pseudo-differential operational amplification instead of said traditional differential OTA.

20. A system as recited in claim 17, wherein said inverter-based integrator circuit further comprises an inverter-based ΣΔ (Sigma-Delta) modulator circuit for performing a ΣΔ analog-to-digital conversion on an input signal, and said inverter-based ΣΔ modulator circuit comprises several single-ended or pseudo-differential inverter-based integrator circuits which include said body-modulated class-C inverter circuits for performing an operational amplification instead of said traditional differential OTAs.
